(19) United States
(12) Patent Application Publication
(10) Pub. No.: US 2026/0304584 A1
(43) Pub. Date: Oct. 1, 2026

(54) LASER SYNCHRONIZATION WITH TARGET MOTION FOR EUV SOURCE OPTIMIZATION

(71) Applicant: KLA Corporation, Milpitas, CA (US)

(72) Inventors: Patrick Tae, San Jose, CA (US); Dmitry Melnik, Milpitas, CA (US); Jian Xu, San Jose, CA (US)

(21) Appl. No.: 19/094,100

(22) Filed: Mar. 28, 2025

(51) Int. Cl. H05G 2/00

(52) U.S. Cl. CPC H05G 2/0082

(57) ABSTRACT

A broadband light source and method are disclosed. The broadband light source may include a rotatable drum at least partially coated with plasma-forming target material, a rotational actuator configured to rotate the rotatable drum, a linear actuator configured to axially translate the rotatable drum, and a laser source configured to direct pulsed illumination to a set of spots on a material-coated portion of the rotatable drum for exciting the plasma-forming target material and emitting broadband light. The broadband light source may include a control system configured to receive laser clock data of the laser source. The control system may be configured to control, in a closed loop synchronized configuration, the actuation of the rotational and linear actuators based on at least the laser clock data to selectively position a plurality of loops of the set of spots on the material-coated portion of the rotatable drum.

### TECHNICAL FIELD

The present disclosure generally relates to generation of broadband illumination and, more particularly, to generation of broadband illumination via a pulsed laser and a rotating drum covered in target material.

### BACKGROUND

As the demand for lithography-based device structures having ever-smaller features continues to increase, the need for improved illumination sources used for inspection of the associated reticles that lithographically print these ever-shrinking devices continues to grow. One such illumination source includes an extreme ultraviolet (EUV) light source. One method of creating EUV light includes spinning a cylinder coated with a uniformly thick layer of solid (frozen) plasma-forming target material, such as xenon, and exposing the xenon-coated portion of the cylinder with a pulsed laser suitable for exciting the xenon to generate plasma. In addition, prior to the next pulse of illumination, the cylinder must be rotated and/or translated to expose a fresh region of solid xenon. As the cylinder rotates, gaseous xenon may be sprayed onto the cold non-illuminated portion of the surface of the cylinder, reforming the frozen xenon layer at previously-illuminated spots in order to fill the portions of the xenon ice consumed by the laser over time. A particular spot or zone is not exposed again until sufficient time has elapsed, allowing for the solid xenon surface to return to its original condition. Adjacent spots must be separated by some minimum distance in order to prevent damage to the cylinder surface.

The plasma creation takes place in a fixed location because the associated collection optics must be aligned to a known location and cannot follow a moving plasma source. The need for the plasma location to be fixed prevents the use of a moving illuminator laser spot. This creates a challenge in applications involving EUV light sources. To allow maximum operational time and inspection uniformity, an inspection tool should have a source of pulsed EUV light that is not interrupted, but rather runs at a chosen pulse frequency for a long period of time (e.g., months).

The creation of EUV light using solid xenon on a rotating cylinder has generally been accomplished with two methods. In the first method, the cylinder, rotating at a constant speed, moves slowly in the axial direction from one end to the other, creating a helix of spots along the cylinder. When the helix intersects the top of the usable length of the xenon ice, the illuminating laser is blocked or turned off until the cylinder's vertical travel stops, and the direction of travel is reversed. The total length of time between subsequent illuminating laser exposures of the same location must be sufficient to allow the xenon ice to reform. The first method is undesirable as it provides non-continuous illumination output.

In the second method, the cylinder is exposed by a laser source in an uninterrupted pattern and allows for the reconditioning of the target regions on the cylinder surface. In this method, the plasma targets may be formed in a first helical pattern (up path) and a return second helical pattern (down path). The second helical pattern may be interleaved with the first helical pattern, which allows for the continuous generation of EUV illumination. Such an approach is described in U.S. Pat. No. 8,963,110, which is incorporated herein by reference in the entirety. Improvements to the second method may include placing the craters in static columns around the drum, separating the craters in the up path from craters in the down path. For instance, triggering a pulsed laser source based on the acquired rotational position information from the rotary encoder is disclosed in U.S. Pat. No. 11,617,256, issued on Mar. 28, 2023, which is incorporated herein by reference in the entirety. For example, an up path may utilize every other column. However, in this method with statically defined columns, only a relatively small fraction of the target is utilized for craters. If higher laser fire rates are desired, then the craters in the static columns may not be fully healed. Furthermore, as the turn-around zones shift phase between the up path and down path columns, then crater overlap of spots may be inevitable in such zones. Crater overlaps in such turn-around zones may cause ice defects when the previous crater has not had sufficient time to heal. Ice defects can reduce illumination intensity and increase xenon demand.

Therefore, it is desirable to provide a method and system that cure the deficiencies of the previous solutions identified above.

### SUMMARY

A broadband light source is disclosed in accordance with one or more illustrative embodiments of the present disclosure. In one illustrative embodiment, the broadband light source may include a rotatable drum at least partially coated with plasma-forming target material. In another illustrative embodiment, the broadband light source may include a rotational actuator configured to rotate the rotatable drum. In another illustrative embodiment, the broadband light source may include a linear actuator configured to axially translate the rotatable drum in an axial direction. In another illustrative embodiment, the broadband light source may include a laser source configured to direct pulsed illumination to a set of spots on a material-coated portion of the rotatable drum for exciting the plasma-forming target material and emitting broadband light as the rotational actuator rotates the rotatable drum and the linear actuator translates the rotatable drum. In another illustrative embodiment, the broadband light source may include a control system configured to receive laser clock data of the laser source and control, in a closed loop synchronized configuration, the actuation of the rotational actuator and the linear actuator based on at least the laser clock data to selectively position a plurality of loops of the set of spots on the material-coated portion of the rotatable drum.

In another illustrative embodiment, for each loop, the set of spots may include a first set of spots arranged in a first spiral pattern from a first end of the rotational drum to a second end of the rotational drum. In another illustrative embodiment, the set of spots may include a set of second end transition spots arranged in a turn-around portion near the second end of the rotational drum. In another illustrative embodiment, the set of spots may include a second set of spots arranged in a second spiral pattern from the second end of the rotational drum to the first end of the rotational drum, where the first set of spots and the second set of spots are interleaved such that spots from the second set of spots do not overlap with spots from the first set of spots. In another illustrative embodiment, the set of spots may include a set of first end transition spots arranged in a turn-around portion near the first end of the rotational drum.

In another illustrative embodiment, between the plurality of loops, the control system may be configured to shift the first spiral pattern a first column-shift distance and shift the second spiral pattern a second column-shift distance. In another illustrative embodiment, the first column-shift distance may be equal to, and in a same direction as, the second column-shift distance. In another illustrative embodiment, a frequency of the pulsed illumination may be a whole integer multiple of the rotations per second of the rotatable drum. In another illustrative embodiment, the control system may be configured to direct the linear actuator to accelerate the rotatable drum above a turn-around threshold speed to reduce a time spent in turn-around portions such that the rotatable drum rotates less than three-quarters of a full rotation in the turn-around portions.

In another illustrative embodiment, the control system may be configured to direct the rotational actuator to actuate the rotatable drum in order to offset the second set of spots such that the spots from the second set of spots do not overlap with the spots from the first set of spots. In another illustrative embodiment, the rotatable drum may include a cylinder. In another illustrative embodiment, the laser source may include a pulsed laser source. In another illustrative embodiment, the broadband light source may include one or more collection optics configured to receive illumination emanated from a plasma generated in response to the excitation of the plasma-forming target material.

In another illustrative embodiment, the broadband light source may include a material source configured to recoat previously-illuminated portions of the rotatable drum with the plasma-forming target material. In another illustrative embodiment, the plasma-forming target material may include at least one of frozen xenon or frozen carbon dioxide. In another illustrative embodiment, the emitted broadband light may include at least one of soft x-ray broadband light or EUV broadband light.

An inspection system is disclosed in accordance with one or more illustrative embodiments of the present disclosure. In one illustrative embodiment, the inspection system may include a broadband light source. In another illustrative embodiment, the broadband light source may include a rotatable drum at least partially coated with plasma-forming target material. In another illustrative embodiment, the broadband light source may include a rotational actuator configured to rotate the rotatable drum and a linear actuator configured to axially translate the rotatable drum. In another illustrative embodiment, the broadband light source may include a laser source configured to direct pulsed illumination to a set of spots on the material-coated portion of the rotatable drum for exciting the plasma-forming target material and emitting broadband light as the rotational actuator rotates the rotatable drum and the linear actuator translates the rotatable drum in an axial direction. In another illustrative embodiment, the inspection system may include a control system configured to receive laser clock data of the laser source and control, in a closed loop synchronized configuration, the actuation of the rotational actuator and the linear actuator based on at least the laser clock data to selectively position a plurality of loops of the set of spots on the material-coated portion of the rotatable drum.

In another illustrative embodiment, for each loop, the set of spots may include a first set of spots arranged in a first spiral pattern from a first end of the rotational drum to a second end of the rotational drum. In another illustrative embodiment, the set of spots may include a set of second end transition spots arranged in a turn-around portion near the second end of the rotational drum. In another illustrative embodiment, the set of spots may include a second set of spots arranged in a second spiral pattern from the second end of the rotational drum to the first end of the rotational drum, where the first set of spots and the second set of spots are interleaved such that spots from the second set of spots do not overlap with spots from the first set of spots. In another illustrative embodiment, the set of spots may include a set of first end transition spots arranged in a turn-around portion near the first end of the rotational drum.

In another illustrative embodiment, the inspection system may include one or more collection optics configured to collect illumination emanated from a plasma generated in response to the excitation of the plasma-forming target material. In another illustrative embodiment, the inspection system may include a set of illuminator optics configured to direct the illumination from the one or more collection optics to one or more samples disposed on a stage. In another illustrative embodiment, the inspection system may include a detector and a set of projection optics configured to receive illumination from a surface of the one or more samples and direct the illumination from the one or more samples to the detector.

In a further aspect, the control system may be configured to shift the first spiral pattern a first column-shift distance and shift the second spiral pattern a second column-shift distance between the plurality of loops. In another aspect, the first column-shift distance may be equal to, and in a same direction as, the second column-shift distance. In another aspect, a frequency of the pulsed illumination may be a whole integer multiple of the rotations per second of the rotatable drum. In another aspect, the control system may be configured to direct the linear actuator to accelerate the rotatable drum above a turn-around threshold speed to reduce a time spent in turn-around portions such that the rotatable drum rotates less than three-quarters of a full rotation in the turn-around portions. In another aspect, the control system may be configured to direct the rotational actuator to actuate the rotatable drum in order to offset the second set of spots such that the spots from the second set of spots do not overlap with the spots from the first set of spots.

In another illustrative embodiment, the rotatable drum may include a cylinder. In another illustrative embodiment, the laser source may include a pulsed laser source. In another illustrative embodiment, the inspection system may include a material source configured to recoat previously-illuminated portions of the rotatable drum with the plasma-forming target material. In another illustrative embodiment, the plasma-forming target material may include at least one of frozen xenon or frozen carbon dioxide. In another illustrative embodiment, the emitted broadband light may include at least one of soft x-ray broadband light or EUV broadband light.

A broadband light source is disclosed in accordance with one or more illustrative embodiments of the present disclosure. In one illustrative embodiment, the broadband light source may include a control system. In another illustrative embodiment, the control system may be configured to receive laser clock data of a laser source. In another illustrative embodiment, the control system may be configured to control, in a closed loop synchronized configuration, an actuation of a rotational actuator and a linear actuator based on at least the laser clock data to selectively position a plurality of loops of a set of spots on a material-coated portion of a rotatable drum. In another illustrative embodiment, the set of spots for each loop may include a first set of spots arranged in a first spiral pattern from a first end of the rotational drum to a second end of the rotational drum. In another illustrative embodiment, the set of spots may include a set of second end transition spots arranged in a turn-around portion near the second end of the rotational drum. In another illustrative embodiment, the set of spots may include a second set of spots arranged in a second spiral pattern from the second end of the rotational drum to the first end of the rotational drum, where the first set of spots and the second set of spots are interleaved such that spots from the second set of spots do not overlap with spots from the first set of spots. In another illustrative embodiment, the set of spots may include a set of first end transition spots arranged in a turn-around portion near the first end of the rotational drum.

A method is disclosed in accordance with one or more illustrative embodiments of the present disclosure. In one illustrative embodiment, the method may include receiving laser clock data of a laser source configured to direct pulsed illumination to a set of spots on a material-coated portion of a rotatable drum for exciting a plasma-forming target material and emitting broadband light as a rotational actuator rotates the rotatable drum and a linear actuator translates the rotatable drum in an axial direction. In another illustrative embodiment, the method may include controlling, in a closed loop synchronized configuration, an actuation of the rotational actuator and the linear actuator based on at least the laser clock data to selectively position a plurality of loops of the set of spots on the material-coated portion of the rotatable drum. In another illustrative embodiment, the set of spots for each loop may include a first set of spots arranged in a first spiral pattern from a first end of the rotational drum to a second end of the rotational drum. In another illustrative embodiment, the set of spots may include a set of second end transition spots arranged in a turn-around portion near the second end of the rotational drum. In another illustrative embodiment, the set of spots may include a second set of spots arranged in a second spiral pattern from the second end of the rotational drum to the first end of the rotational drum where the first set of spots and the second set of spots are interleaved such that spots from the second set of spots do not overlap with spots from the first set of spots. In another illustrative embodiment, the set of spots may include a set of first end transition spots arranged in a turn-around portion near the first end of the rotational drum. In another illustrative embodiment, the method may include recoating previously targeted spots of the rotatable drum with the plasma-forming target material.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF THE DRAWINGS

The numerous advantages of the disclosure may be better understood by those skilled in the art by reference to the accompanying figures.

FIGS. 1A and 1B illustrate a simplified conceptual view of a broadband light source for generating a continuous or near-continuous plasma-based illumination output, in accordance with one or more embodiments of the present disclosure.

FIG. 2A illustrates a conceptual view of a first set of spots and a second set of spots distributed across the surface of the rotatable drum of the broadband light source, in accordance with one or more additional and/or alternative embodiments of the present disclosure.

FIG. 2B illustrates a conceptual view of a sub-revolution turn-around portion of the rotatable drum, in accordance with one or more additional and/or alternative embodiments of the present disclosure.

FIG. 3 illustrates shifting spiral patterns a predetermined distance, in accordance with one or more additional and/or alternative embodiments of the present disclosure.

FIG. 4 illustrates a block diagram view of an inspection system incorporating the broadband light source, in accordance with one embodiment of the present disclosure.

FIG. 5 illustrates a flow diagram depicting a method for generating continuous or near-continuous broadband light, in accordance with one or more embodiment of the present disclosure.

### DETAILED DESCRIPTION

The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure. Reference will now be made in detail to the subject matter disclosed, which is illustrated in the accompanying drawings.

Current methodologies for controlling laser pulsing and target motion include running them ‘open-loop’, without synchronization based on the laser clock. For example, “triggering a pulsed laser source based on the acquired rotational position information from the rotary encoder” is disclosed in U.S. Pat. No. 11,617,256, titled “LASER AND DRUM CONTROL FOR CONTINUOUS GENERATION OF BROADBAND LIGHT”, issued on Mar. 28, 2023, which is incorporated herein by reference in the entirety.

Current methodologies may use static spiral patterns to define and control where spots are located, to keep the upstroke and downstroke spots from overlapping each other. In some embodiments the columns are located in fixed positions controlled by a rotary encoder. While this may keep the spots separate from each other, if higher laser fire rates are desired, then the static columns may not be fully healed. For example, an up path may utilize every other column. However, in this method with statically defined columns, only a relatively small fraction of the target is utilized for craters. It is more desirable to have the craters uniformly cover the full ice surface. In embodiments of the present disclosure, it is contemplated that gradually shifting the columns horizontally over time may create more uniform coverage of craters, which may be done with an additional phase shift at the translation turnarounds.

Furthermore, as the turn-around zones shift phase between the upstroke and downstroke columns, then crater overlap of spots may be inevitable in such zones. Crater overlaps may cause ice defects when the previous crater has not had sufficient time to heal. Ice defects can reduce illumination intensity and increase xenon demand. To address this, it is important to minimize the amount of time spent in the turnaround portion of the trajectory. Time in the turnarounds may be reduced by configurations that increase acceleration and optimize the translation trajectory during the turnaround. The effect is that the vertical energy density of laser radiation in the turnaround regions is reduced. Indeed, it is contemplated herein that empirically the ice has been observed to be stable using such configurations of embodiments of the present disclosure.

Embodiments of the present disclosure are directed to the exposure of a rotating drum (e.g., cylinder) covered in plasma-forming material, which may be excited via an illumination source to emit broadband light from a set of uninterrupted target spot locations. In embodiments, the rotation and linear translation of the rotatable drum are synced in a combined closed-loop control methodology that is controlled based on the laser source. In this way, rather than the laser being triggered by the actuating of the rotatable drum, the actuating of the rotatable drum may be based on the laser source. In embodiments, the two sets of spiral patterns of spots in the upstroke and downstroke, respectively, are shifted radially (e.g., horizontally) around the rotatable drum over time to further reduce crater overlaps and provide more uniform crater distribution and healing. In embodiments, the linear actuation may be controlled to reduce a time spent in turn-around transition zones at the ends of the rotatable drum where the linear actuator reverses direction. For example, the linear actuation may be sped up above a threshold rate needed to complete the turn-around in less than one revolution of the rotatable drum.

Embodiments herein illustrate new methodologies for generating evenly spaced spots on a drum. These methodologies may greatly reduce crater overlaps, reduce xenon consumption, improve scalability to higher impulse firing rates, improve light source brightness, improve light source stability, or the like. For example, embodiments of the present disclosure may reduce output variation by about a factor of one third.

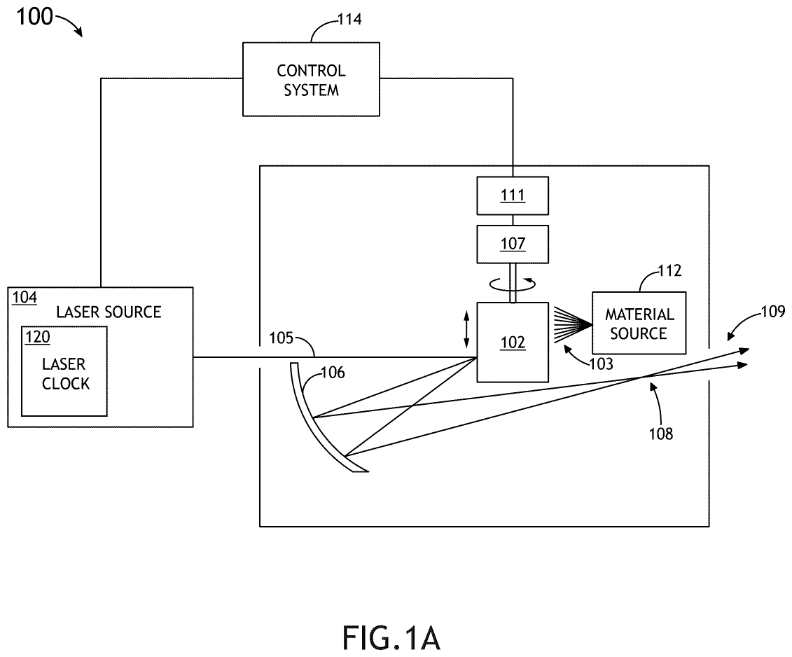

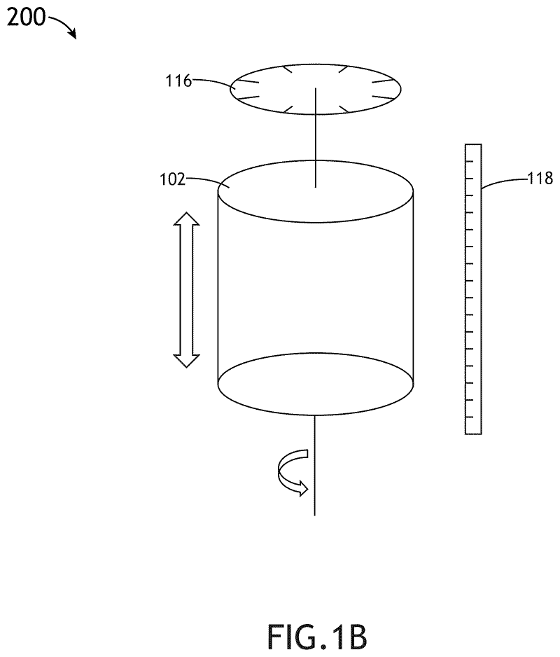

FIGS. 1A through 5 generally illustrate embodiments of a system and method for generating closed-loop continuous or near-continuous plasma-based illumination output, in accordance with one or more embodiments of the present disclosure.

Additional embodiments of the present disclosure provide for a reticle inspection system, a wafer inspection system, or a lithography system (or other optical system) incorporating the plasma-based light source described herein.

FIGS. 1A and 1B illustrate a simplified conceptual view of a broadband light source 100 for generating a continuous or near-continuous plasma-based illumination output, in accordance with one or more embodiments of the present disclosure.

In embodiments, the broadband light source 100 includes a rotatable drum 102 suitable for rotation about an axis. For example, the rotatable drum 102 may be a cylinder, as shown in FIG. 1A. In other embodiments, the rotatable drum 102 includes any cylindrically-symmetric shape known in the art. For example, the rotatable drum 102 may include a cone, a sphere, an ellipsoid and the like. Further, the rotatable drum 102 may include a composite shape consisting of two or more shapes. It is noted herein that for the purposes of descriptive convenience the broadband light source 100 and related embodiments are described in the context of a rotatable drum 102, as depicted in FIG. 1A, however this embodiment should not be interpreted as a limitation on the scope of the present disclosure.

In embodiments, the rotatable drum 102 is at least partially coated with a plasma-forming target material 103. The plasma-forming target material 103 may include any material known in the art that generates plasma when excited by an illumination source and subsequently emits broadband light. For example, the target material 103 may include a solid material disposed on the surface of the rotatable drum 102. The broadband light emitted by the plasma may include, but is not limited to, broadband soft x-ray light, broadband EUV light, broadband DUV light, broadband VUV light, broadband UV light, broadband visible light, and/or broadband IR light. For example, the target material 103 may include, but is not limited to, xenon frozen onto the surface of the rotatable drum 102. It is noted that the utilization of frozen xenon as a target material 103 may be particularly useful in the context of generating broadband EUV light. By way of another example, the target material 103 may include, but is not limited to, carbon dioxide frozen onto the surface of the rotatable drum 102. It is noted that the utilization of frozen carbon dioxide as a target material 103 may be particularly useful in the context of generating broadband soft x-ray light.

In embodiments, the broadband light source 100 includes a pulsed illumination source 104. The pulsed illumination source 104 may include any pulsed or modulated illumination source known in the art. For example, the pulsed illumination source 104 may include a pulsed laser source. Further, the pulsed illumination source is suitable for initiating and/or maintaining a plasma in the material 103. For example, the pulsed illumination source 104 may include, but is not limited to, one or more infrared (IR) lasers. For instance, the pulsed illumination source 104 may include one or more CO2 lasers.

In embodiments, the broadband light source 100 includes a laser clock 120. For example, the laser source 104 may be coupled to, or include, the laser clock 120. The laser clock 120 may include a system clock or processor clock (e.g., a microcontroller or embedded processor) of the laser source 104 which governs the timing of operations and outputs the laser clock data to the control system 114. For instance, the laser clock data may include a frequency and timing (e.g., global timestamp) of the pulsed illumination, an operating frequency of the laser source 104 (e.g., laser controller clock rate), and/or the like.

In embodiments, the broadband light source 100 includes one or more actuators configured to actuate the rotatable drum 102 rotationally and axially. In embodiments the broadband light source 100 includes a rotational actuator 107 configured to rotate the rotatable drum 102 about an axis. The rotational actuator 107 may include any rotational actuator known in the art such as one or more servo motors. Additionally, the broadband light source 100 may include a linear actuator 111 configured to translate the rotatable drum 102 along an axial direction (e.g., vertical direction in the example shown in FIG. 1A). It is recognized herein that the present disclosure is not limited to the actuators 107, 111 in FIG. 1A. As such, the description provided above should be interpreted merely as illustrative. For instance, the pulsed illumination source 104 may be disposed on an actuating stage (not shown), which provides translation of the pulsed illumination 105 relative to the rotatable drum 102.

The axial translation provided by the linear actuator 111 and the rotation imparted by rotational actuator 107 enable the pulsed illumination 105 to trace a pattern of spots across the rotatable drum 102.

In embodiments, the control system 114 may be used to control the actuation of the rotatable drum 102 along the rotational direction and/or the axial direction. In embodiments, the control system 114 may be communicatively coupled to the rotational actuator 107 and/or the linear actuator 107 and/or the pulsed laser source 104. In this regard, the control system 114 may direct the actuators 107, 111 and the rotatable drum 102 to trace the pulsed illumination 105 across a surface as the rotatable drum 102 rotates and axially translates, in any manner described in the present disclosure.

In embodiments, the broadband light source 100 includes one or more encoders. For example, as shown in FIG. 1B, the system may include a rotary encoder 116. The rotary encoder 116 may be mechanically attached to the rotational actuator 107. In this sense, the rotary encoder 116 may be integrated with the rotational actuator 107 and configured to indicate a rotational position of the rotatable drum 102, which is in turn coupled to the rotational actuator 107 via a shaft. In embodiments, the position indicator information from the rotary encoder 116 may be electronically read out of the rotary encoder 116 via a control system 114 (e.g., via electrical wires from the rotary encoder 116). This position indicator information may then be utilized by the control system 114 to control or adjust the positions of the set of spots based on the pulsed laser source 104. For example, a particular position of the rotatable drum 102 may be selectively aligned with the laser source 104 exactly at the same time when the laser source 104 is about to fire to control the position of a corresponding spot on the rotatable drum 102. For instance, the rotational actuator 107 and/or linear actuator may be accelerated and/or decelerated or the like to control the positions of spots.

In embodiments, the broadband light source 100 may utilize a linear encoder 118 to control certain aspects of the rotatable drum 102. The linear encoder 118 may be mechanically attached to the linear actuator 111. In this sense, the linear encoder 118 may be integrated with the linear actuator 111 and configured to indicate an axial (e.g., vertical) position of the rotatable drum 102. In embodiments, the position indicator information from the linear encoder 118 may also be electronically read out of the linear encoder 118 via the control system 114 (e.g., via electrical wires from the linear encoder 118).

In embodiments, the broadband light source 100 includes a material source 112. The material source 112 may contain material used to coat the rotatable drum 102. For example, the material source 112 may be used to apply a selected material to the surface of the rotatable drum 102. In embodiments, the material source 112 may direct a gas, liquid stream, or spray onto the surface of the rotatable drum 102 as it rotates and is maintained at a temperature below the freezing point of the selected material. For example, the selected material may include, but is not limited to, xenon, carbon dioxide, and like materials. For instance, in the case of xenon, the rotatable drum 102 may be cooled below the xenon freezing point (e.g., −111.8° C.). Then, xenon may be applied to the surface of the rotatable drum 102 causing the xenon to freeze onto the surface of the rotatable drum 102 as it is rotated, thereby forming a solid xenon layer on the surface of the rotatable drum 102. In another instance, in the case of carbon, the rotatable drum 102 may be cooled below the carbon dioxide freezing point (e.g., −78° C.). Then, carbon dioxide may be applied to the surface of the rotatable drum 102 causing the carbon dioxide to freeze onto the surface of the rotatable drum 102 as it is rotated, thereby forming a solid carbon dioxide layer on the surface of the rotatable drum 102. In embodiments, the rotatable drum 102 may include an internal reservoir for containing a coolant material. For example, the rotatable drum 102 may include an internal reservoir holding a volume of liquid nitrogen used to cool the applied xenon or carbon dioxide below the freezing point for the respective material. In embodiments, the material source 112 is configured to recoat portions of the rotatable drum 102 with the plasma-forming target material 103. For example, the material source 112 is configured to recoat previously-illuminated portions of the rotatable drum 102 with the plasma-forming target material 103. For instance, the material source 112 may recoat spots previously cratered by illumination 105 with a plasma-forming material, such as xenon or carbon dioxide. Further, the length of the rotatable drum 102 and the vertical speed of the rotatable drum 102 may be selected so as to provide ample time for the plasma-forming material (e.g., xenon or carbon dioxide) to solidify on the rotatable drum 102 before the next illumination exposure.

In embodiments, the broadband light source 100 includes one or more collection optics 106 configured to receive illumination emanating from a plasma generated in response to the excitation of the plasma-forming target material. In embodiments, the collection optics 106 are positioned to collect the illumination generated on the rotatable drum 102 surface by the laser source 104. For example, the collection optics 106 may include any collector or collection optics known in the art of collection optics. For instance, in the case of EUV light generation, the collection optics 106 may include any collector or collection optics known in the art compatible with EUV light. In another instance, in the case of soft x-ray light generation, the collection optics 106 may include any collector or collection optics known in the art compatible with soft x-ray light. In embodiments, the collection optics 106 may direct and/or focus illumination 109 emanating from the rotatable drum 102 to one or more downstream optical elements. In embodiments, the collection optics 106 may be configured to focus illumination emanating from the rotatable drum 102 to an intermediate focus 108, as shown in FIG. 1A.

In embodiments, the control system 114 directs the rotational actuator 107 and/or the linear actuator 111 in order to control the rotational and/or linear motion (position, speed, and acceleration) of the rotatable drum 102.

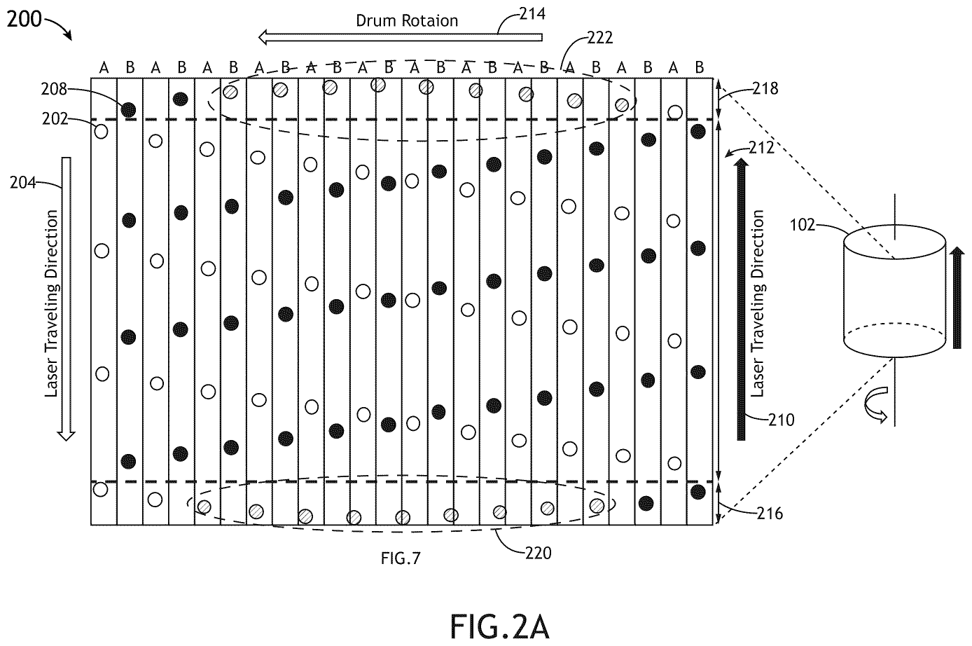

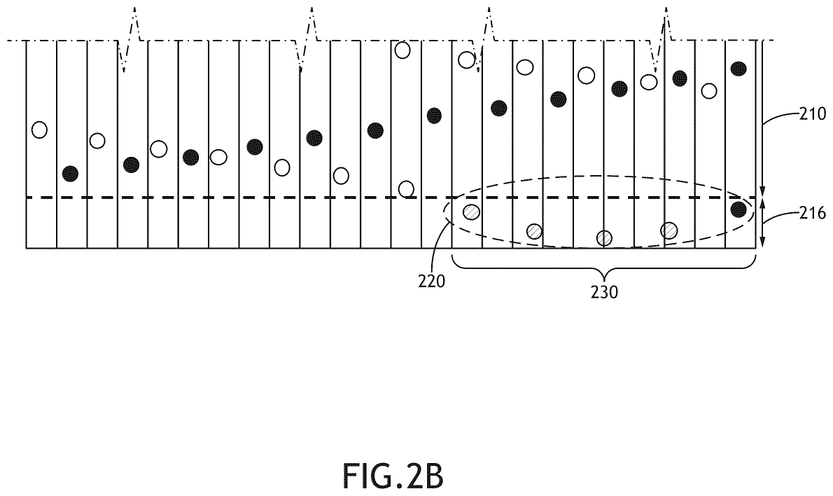

FIG. 2A illustrates a conceptual view 200 of a first set of spots 202 and a second set of spots 208 distributed across the surface of the rotatable drum 102 of the broadband light source 100, in accordance with one or more embodiments of the present disclosure.

In embodiments, the first and second sets of spots 202, 208 correspond to first and second spiral patterns.

In embodiments, as the rotatable drum 102 is rotated the pulsed illumination source 104 directs pulsed illumination to a first set of spots 202 traversing a material-coated portion of the rotatable drum 102. Additionally, as the rotatable drum 102 continues to rotate, the pulsed illumination source 104 directs pulsed illumination to a second set of spots 208 traversing the material-coated portion of the rotatable drum 102 in a second direction. In embodiments, the first set of spots 202 and the second set of spots 208 each form a spiral pattern about a surface (e.g., xenon surface) of the rotatable drum 102. Note that the surface depicted in FIG. 2A is representative of a cylindrical surface spanning −180° to +180° about the axis of the cylinder along a rotational direction 214. In embodiments, the rotatable drum 102 may be rotated at a selected constant rotational velocity (e.g., constant drum RPM) in an overlap region 212 along the rotational direction. In embodiments, the rotatable drum 102 may be rotationally decelerated/accelerated in the turn-around portions 216, 218.

In embodiments, for each loop, the sets of spots 202, 208 are positioned for an upstroke, a first turn-around transition, a downstroke, and a second turn-around transition. Each loop of the sets of spots 202, 208 may define one full cycle that returns the rotatable drum 102 back to a starting axial position. For example, the spots may include a first set of spots 202 arranged in a first spiral pattern in a first direction 204 (downstroke) from a first end of the rotatable drum 102 to a second end of the rotatable drum 102. The set of spots 202 may include a set of second end transition spots 220 arranged in a turn-around portion 216 near the second end of the rotatable drum 102. The set of spots 202 may include a second set of spots 208 arranged in a second spiral pattern in the second direction 210 (upstroke) from the second end of the rotatable drum 102 to the first end of the rotatable drum 102. The set of spots 202 may include a set of first end transition spots 222 arranged in a turn-around portion 218 near the first end of the rotatable drum 102.

The first set of spots and the second set of spots are interleaved such that spots from the second set of spots does not overlap with spots from the first set of spots. In this regard, the first set of spots may form a first spiral (or helical, or column) pattern during rotational and axial acceleration of the rotatable drum 102, while the second set of spots form a return second spiral (or helical or column) pattern that avoids overlapping the first pattern. Examples of such patterns are discussed in greater detail further herein.

In embodiments, the control system 114 may utilize the laser clock 120 (as opposed to the rotational positional information) as a triggering reference. In this regard, the laser clock 120 may act as the primary triggering reference for the pulsed laser source 104 and may be used a reference when controlling the rotational and/or vertical motion of the rotatable drum 102.

FIG. 2B illustrates a conceptual view of a sub-revolution turn-around portion 230 (i.e., transition period) of the rotatable drum 102, in accordance with one or more additional and/or alternative embodiments of the present disclosure.

In embodiments, in the turn-around portions 216, 218, the rotatable drum 102 may be accelerated (or decelerated) to impart a temporary increase (or decrease) in rotational speed of the rotatable drum 102, to minimize dwell time in these areas.

In embodiments, the control system 114 is configured to direct the linear actuator 111 to accelerate the rotatable drum 102 above a turn-around threshold speed to reduce a time spent in turn-around portions such that the rotatable drum rotates less than three-quarters of a full rotation in the turn-around portions. For example, the turn-around threshold speed may include a speed (e.g., peak speed) that is at least two times a constant-velocity speed used in the constant velocity region 212.

In embodiments, any number of spiral patterns may be used. For example, the spiral patterns corresponding to the first and second sets of spots 202, 208 may be expanded to include a third spiral pattern corresponding to a third set of spots in the first direction. For example, the spiral patterns may include two, three, four, or more spiral patterns in a series, each corresponding to respective sets of spots on the rotatable drum 102.

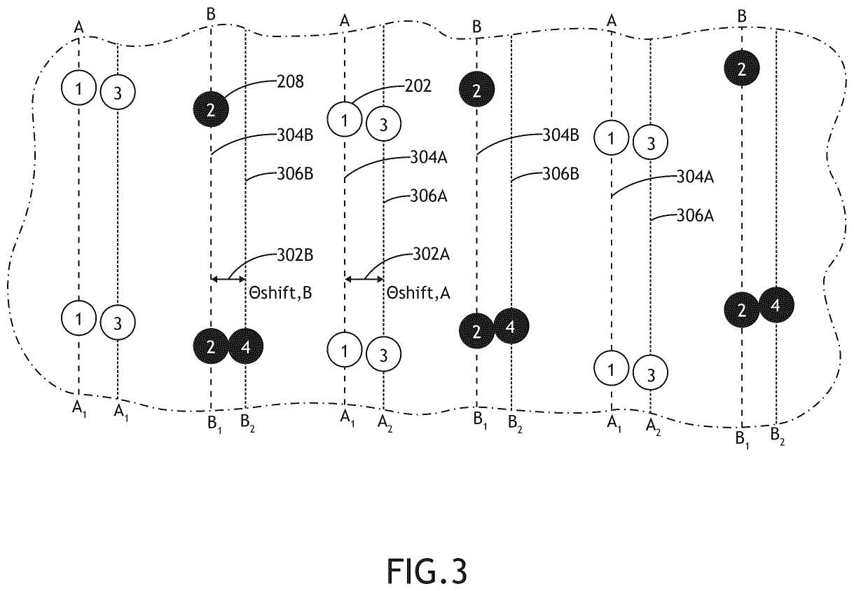

FIG. 3 illustrates a shift of spiral patterns a predetermined distance, wherein the spiral patterns correspond to the sets of spots 202, 208, in accordance with one or more additional and/or alternative embodiments of the present disclosure. For example, the first set of spots 202 may be aligned along a first spiral pattern (e.g., helical pattern) and the second set of spots 202 may be aligned along a second spiral pattern.

Between the plurality of loops, the control system 114 may be configured to shift the first spiral pattern a first column-shift distance 302A. The control system 114 may be further configured to shift the second spiral pattern a second column-shift distance 302B. Such shifting may provide for a more uniform distribution of spots over many loops. For example, the broadband light source 100 may be run continuously over many days, weeks, or months. The shifting of the spiral patterns over time may reduce overuse of particular areas (e.g., columns) of the rotatable drum 102. In at least some examples, this means that the spots are not always aligned with static rotational encoder positions. For example, such a shifting of the columns may be configured to be performed in addition to the phase shift occurring in the turn-around portions 216, 218.

The first column-shift distance 302A may be equal to, and in the same direction as, the second column-shift distance 302B.

In embodiments, any number of column-shift distances may be implemented. For example, in addition to the first column-shift distance 302A and the second column-shift distance 302B, the control system 114 may be configured to implement a third column-shift distance, a fourth column-shift distance, or the like. For example, the column-shift distances may be equal to each other, or may differ from each other in magnitude and/or direction.

For example, in a first loop, the first set of spots 202 may be positioned along a first-loop first spiral pattern 304A (column A1); and the second set of spots are positioned along a first-loop second spiral pattern 304B (column B1). At the end of the loop, in a second loop, the first set of spots 202 may be positioned along a second-loop first spiral pattern 306A (column A2) offset from the column A1, and the second set of spots 208 may be positioned along a second-loop second column 306B (column B2) offset from the column B1. Over many loops, the spiral patterns of the spots 202, 208 may shift any amount of cumulative distance around the rotatable drum 102.

In embodiments, a frequency of the pulsed illumination 105 may be a whole integer multiple of the rotations per second (e.g., rotations per minute (RPM)/60) of the rotatable drum 102. For example, if the RPM is 600 (i.e., 10 Hz=600/60), then the frequency of the pulsed illumination 105 may be 10,000 Hz, which is exactly 1000 times higher. It should be understood that non-integer multiples (e.g., 999.94 times higher) can result in phase accumulation errors between the laser pulsing frequency and drum rotation over extended operational periods, potentially causing systematic displacement of spot positions. Such a whole integer multiple may improve uniformity of crater distributions.

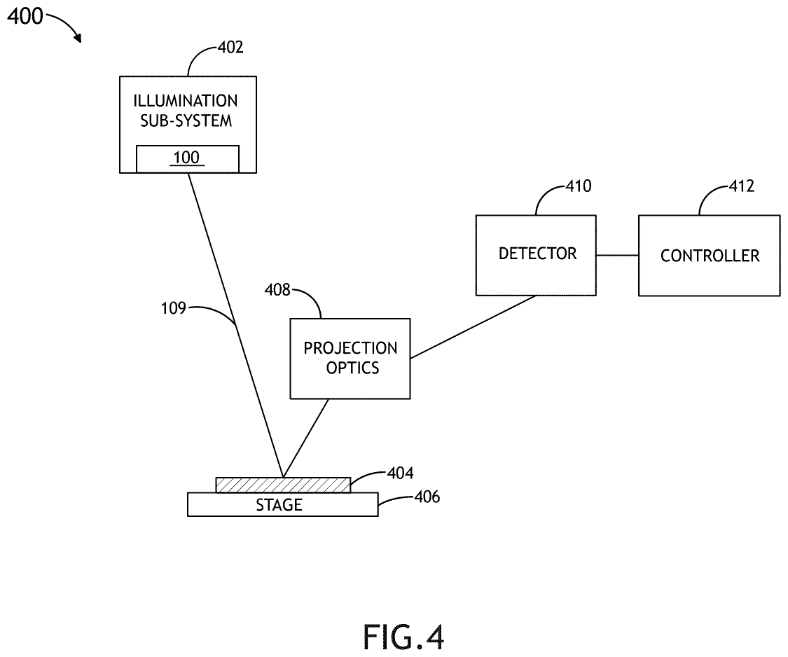

FIG. 4 illustrates a block diagram view of an inspection system 400 incorporating a plasma-based broadband light source 100, in accordance with one or more embodiments of the present disclosure. In embodiments, the system 400 includes an illumination sub-system 402. The illumination sub-system 402 may incorporate the broadband light source 100 described throughout the present disclosure. In embodiments, although not shown in FIG. 4, the system 400 includes a set of illuminator optics. In embodiments, the illuminator optics may direct illumination 109 emanating from the broadband light source 100 to one or more samples 404 disposed on a sample stage 406. The sample stage 406 may include any stage assembly known in the art of inspection systems including an X-Y stage, an R-θ stage, an X-Y θ stage, and the like. For example, the one or more samples 404 may include, but are not limited to, a wafer (e.g., semiconductor wafer). By way of another example, the one or more samples 404 may include, but are not limited to, a reticle or photomask. In embodiments, the system 400 includes one or more detectors 410. In embodiments, the system 400 includes a set of projection optics 408 suitable for collecting light scattered, reflected, diffracted, or otherwise emanating from the specimen and directing the light to the one or more detectors (e.g., CCD, TDI-CCD, PMT and the like). In embodiments, the system 400 includes a controller 412 for receiving and/or analyzing the measurement results from the detector 410.

In embodiments, the inspection system 400 is configured as a wafer inspection system or a reticle/photomask inspection system. For example, the inspection system 400 may include any wafer or reticle/photomask inspection optical architecture known in the art suitable for operating in the EUV spectral range. By way of another example, the inspection system 400 may include any wafer or reticle/photomask inspection optical architecture known in the art suitable for operating in the soft x-ray spectral range. It is further recognized that the inspection system 400 may be configured as an EUV mask or mask blank inspection system. EUV-based mask blank inspection is described generally in U.S. Pat. No. 8,711,346, issued on Apr. 29, 2014, which is incorporated herein by reference in the entirety. EUV-based mask blank inspection is described generally in U.S. patent application Ser. No. 13/417,982, filed on Mar. 12, 2012, which is incorporated herein by reference in the entirety. EUV-based reticle inspection is generally described in U.S. patent application Ser. No. 13/905,448, filed on May 30, 2013, which is incorporated herein by reference in the entirety.

In embodiments, although not shown, the broadband light source 100 described throughout the present disclosure may be implemented within an optical lithography system. In embodiments, the optical lithography system (not shown) may include a set of illuminator optics configured to direct output light from the broadband light source 100 to an EUV-compatible lithography mask (e.g., EUV reflective mask) or a soft x-ray-compatible lithography mask. In embodiments, the optical lithography system includes a set of projection optics configured to receive illumination reflected from the mask and direct the reflected illumination from the mask to one or more wafers disposed on a wafer stage. The optical lithography system may include any broadband lithography system known in the art. EUV-based lithography is described generally in U.S. patent application Ser. No. 13/419,042, filed on Mar. 13, 2012, which is incorporated herein by reference in the entirety.

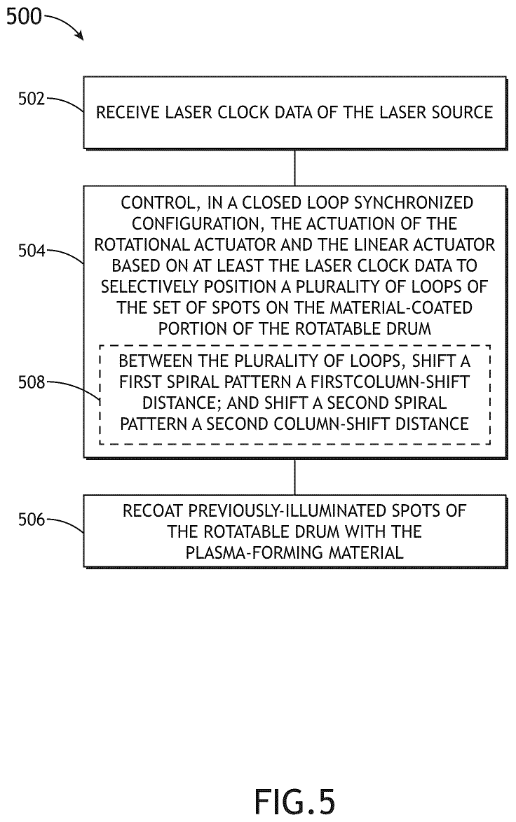

FIG. 5 illustrates a flow diagram depicting a method 500 for generating continuous or near-continuous plasma-based illumination, in accordance with one embodiment of the present disclosure. It is noted that the embodiments and enabling technologies described previously herein in the context of the inspection system 400 should be interpreted to extend to the method 500. It is further noted herein that the steps of method 500 may be implemented all or in part by inspection system 400. It is further recognized, however, that the method 500 is not limited to the inspection system 400 in that additional or alternative system-level embodiments may carry out all or part of the steps of method 500.

An optional step includes at least partially coating the rotatable drum 102 with a plasma-forming target material as the rotatable drum is rotated. For example, as noted above the material source 112 may be used to coat the rotatable drum 102.

A step 502 includes receiving laser clock data of the laser source 104. In embodiments, the control system 114 may be communicatively coupled to and configured to receive the laser clock data from the laser clock 120.

A step 504 includes controlling the actuation of the rotational actuator 107 and the linear actuator 111 based on at least the laser clock data to selectively position a plurality of loops of the set of spots 202 on the material-coated portion of the rotatable drum 102.

In a closed loop synchronized configuration, the control system 114 may include various feedback mechanisms. For example, the control system 114 may synchronize the actuation of the rotational actuator 107 and the linear actuator 111 based on combinations of the laser clock data, the position indicator information from the rotary encoder 116, the position indicator information from the linear encoder 118, target healing data, and/or the like.

The synchronization may be implemented using various control algorithms including proportional-integral-derivative (PID) control, model predictive control, adaptive control, or the like. In this way, the laser clock 120 (as opposed to the acquired rotational position information from the rotary encoder) may be utilized as a triggering reference for the pulsed laser source 104. The laser clock 120 may act as the primary triggering reference when controlling the rotational and/or linear motion of the rotatable drum 102.

This closed-loop control based on the laser clock data may enable precise and repeatable positioning of the laser pulse spots on a drum surface over multiple loops, providing a more uniform distribution of spots and reducing overuse of particular areas of the rotatable drum 102.

An optional step includes acquiring a rotational position information of the rotatable drum 102. For example, as shown in FIGS. 1A-5, the control system 114 may read out one or more electrical signals from a rotary encoder 116 integrated with the rotational actuator 107 and connected to the rotatable drum 102. In addition, the control system 114 may read out one or more electrical signals from a linear encoder 118 integrated with the linear actuator 111 and connected to the rotatable drum 102.

A step 506 includes recoating previously-illuminated spots of the rotatable drum 102 with the plasma-forming material. For example, as shown in FIG. 1A, after exposure to an illumination 105 from the pulsed laser source 104, the material source 112 may recoat the rotatable drum 102 with the selected plasma-forming material (e.g., xenon or carbon dioxide), allowing the spots of the first and second patterns described previously herein to be re-exposed to illumination 105 on one or more subsequent passes.

An optional sub-step 508 may include shifting the first spiral pattern the first column-shift distance 302A, and shifting the second spiral pattern the second column-shift distance 302B. For example, as shown in FIG. 3, the first positions 304A, 304B of the first and second spiral patterns, respectively, may be shifted to second positions 306A, 306B.

In embodiments, any number of loops of the set of spots may be used, such as running continuously for many days. For example, the plurality of loops may include a third loop. By way of another example, the plurality of loops may include thousands of loops, millions of loops, or the like.

One skilled in the art will recognize that the herein described components (e.g., operations), devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components (e.g., operations), devices, and objects should not be taken as limiting.

Those having skill in the art will appreciate that there are various vehicles by which processes and/or systems and/or other technologies described herein can be effected (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; alternatively, if flexibility is paramount, the implementer may opt for a mainly software implementation; or, yet again alternatively, the implementer may opt for some combination of hardware, software, and/or firmware. Hence, there are several possible vehicles by which the processes and/or devices and/or other technologies described herein may be effected, none of which is inherently superior to the other in that any vehicle to be utilized is a choice dependent upon the context in which the vehicle will be deployed and the specific concerns (e.g., speed, flexibility, or predictability) of the implementer, any of which may vary.

The previous description is presented to enable one of ordinary skill in the art to make and use the invention as provided in the context of a particular application and its requirements. Various modifications to the described embodiments will be apparent to those with skill in the art, and the general principles defined herein may be applied to other embodiments. Therefore, the present invention is not intended to be limited to the particular embodiments shown and described, but is to be accorded the widest scope consistent with the principles and novel features herein disclosed.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

All of the methods described herein may include storing results of one or more steps of the method embodiments in memory. The results may include any of the results described herein and may be stored in any manner known in the art. The memory may include any memory described herein or any other suitable storage medium known in the art. After the results have been stored, the results can be accessed in the memory and used by any of the method or system embodiments described herein, formatted for display to a user, used by another software module, method, or system, and the like. Furthermore, the results may be stored “permanently,” “semi-permanently,” temporarily,” or for some period of time. For example, the memory may be random access memory (RAM), and the results may not necessarily persist indefinitely in the memory.

It is further contemplated that each of the embodiments of the method described above may include any other step(s) of any other method(s) described herein. In addition, each of the embodiments of the method described above may be performed by any of the inspection systems described herein.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

We claim:

1. A broadband light source comprising:
a rotatable drum at least partially coated with plasma-forming target material;
a rotational actuator configured to rotate the rotatable drum;
a linear actuator configured to axially translate the rotatable drum in an axial direction;
a laser source configured to direct pulsed illumination to a set of spots on a material-coated portion of the rotatable drum for exciting the plasma-forming target material and emitting broadband light as the rotational actuator rotates the rotatable drum and the linear actuator translates the rotatable drum; and
a control system, wherein the control system is configured to:
receive laser clock data of the laser source; and
control, in a closed loop synchronized configuration, the actuation of the rotational actuator and the linear actuator based on at least the laser clock data to selectively position a plurality of loops of the set of spots on the material-coated portion of the rotatable drum,
wherein for each loop, the set of spots are positioned such that the set of spots comprise:
a first set of spots arranged in a first spiral pattern from a first end of the rotational drum to a second end of the rotational drum;
a set of second end transition spots arranged in a turn-around portion near the second end of the rotational drum;
a second set of spots arranged in a second spiral pattern from the second end of the rotational drum to the first end of the rotational drum, wherein the first set of spots and the second set of spots are interleaved such that spots from the second set of spots do not overlap with spots from the first set of spots; and
a set of first end transition spots arranged in a turn-around portion near the first end of the rotational drum.

2. The broadband light source of claim 1, wherein, between the plurality of loops, the control system is further configured to:
shift the first spiral pattern a first column-shift distance; and
shift the second spiral pattern a second column-shift distance.

3. The broadband light source of claim 2, wherein the first column-shift distance is equal to, and in a same direction as, the second column-shift distance.

4. The broadband light source of claim 1, wherein a frequency of the pulsed illumination is a whole integer multiple of the rotations per second of the rotatable drum.

5. The broadband light source of claim 1, wherein the control system is configured to direct the linear actuator to accelerate the rotatable drum above a turn-around threshold speed to reduce a time spent in turn-around portions such that the rotatable drum rotates less than three-quarters of a full rotation in the turn-around portions.

6. The broadband light source of claim 1, wherein the control system is configured to direct the rotational actuator to actuate the rotatable drum in order to offset the second set of spots such that the spots from the second set of spots do not overlap with the spots from the first set of spots.

7. The broadband light source of claim 1, wherein the rotatable drum comprises:
a cylinder.

8. The broadband light source of claim 1, wherein the laser source comprises a pulsed laser source.

9. The broadband light source of claim 1, further comprising one or more collection optics configured to receive illumination emanated from a plasma generated in response to the excitation of the plasma-forming target material.

10. The broadband light source of claim 1, further comprising:
a material source configured to recoat previously-illuminated portions of the rotatable drum with the plasma-forming target material.

11. The broadband light source of claim 1, wherein the plasma-forming target material comprises at least one of frozen xenon or frozen carbon dioxide.

12. The broadband light source of claim 1, wherein the emitted broadband light comprises at least one of soft x-ray broadband light or EUV broadband light.

13. An inspection system comprising:
a broadband light source, wherein the broadband light source comprises:
a rotatable drum at least partially coated with plasma-forming target material;
a rotational actuator configured to rotate the rotatable drum;
a linear actuator configured to axially translate the rotatable drum;
a laser source configured to direct pulsed illumination to a set of spots on a material-coated portion of the rotatable drum for exciting the plasma-forming target material and emitting broadband light as the rotational actuator rotates the rotatable drum and the linear actuator translates the rotatable drum in an axial direction;
a control system, wherein the control system is configured to:
receive laser clock data of the laser source; and
control, in a closed loop synchronized configuration, the actuation of the rotational actuator and the linear actuator based on at least the laser clock data to selectively position a plurality of loops of the set of spots on the material-coated portion of the rotatable drum,
wherein for each loop, the set of spots are positioned such that the set of spots comprise:
a first set of spots arranged in a first spiral pattern from a first end of the rotational drum to a second end of the rotational drum;
a set of second end transition spots arranged in a turn-around portion near the second end of the rotational drum;
a second set of spots arranged in a second spiral pattern from the second end of the rotational drum to the first end of the rotational drum, wherein the first set of spots and the second set of spots are interleaved such that spots from the second set of spots do not overlap with spots from the first set of spots; and
a set of first end transition spots arranged in a turn-around portion near the first end of the rotational drum;
one or more collection optics configured to collect illumination emanated from a plasma generated in response to the excitation of the plasma-forming target material;
a set of illuminator optics configured to direct the illumination from the one or more collection optics to one or more samples disposed on a stage;
a detector; and
a set of projection optics configured to receive illumination from a surface of the one or more samples and direct the illumination from the one or more samples to the detector.

14. The inspection system of claim 13, wherein, between the plurality of loops, the control system is further configured to:
shift the first spiral pattern a first column-shift distance; and
shift the second spiral pattern a second column-shift distance.

15. The inspection system of claim 14, wherein the first column-shift distance is equal to, and in a same direction as, the second column-shift distance.

16. The inspection system of claim 13, wherein a frequency of the pulsed illumination is a whole integer multiple of the rotations per second of the rotatable drum.

17. The inspection system of claim 13, wherein the control system is configured to direct the linear actuator to accelerate the rotatable drum above a turn-around threshold speed to reduce a time spent in turn-around portions such that the rotatable drum rotates less than three-quarters of a full rotation in the turn-around portions.

18. The inspection system of claim 13, wherein the control system is configured to direct the rotational actuator to actuate the rotatable drum in order to offset the second set of spots such that the spots from the second set of spots do not overlap with the spots from the first set of spots.

19. The inspection system of claim 13, wherein the rotatable drum comprises:
a cylinder.

20. The inspection system of claim 13, wherein the laser source comprises a pulsed laser source.

21. The inspection system of claim 13, further comprising:
a material source configured to recoat previously-illuminated portions of the rotatable drum with the plasma-forming target material.

22. The inspection system of claim 13, wherein the plasma-forming target material comprises at least one of frozen xenon or frozen carbon dioxide.

23. The inspection system of claim 13, wherein the emitted broadband light comprises at least one of soft x-ray broadband light or EUV broadband light.

24. A broadband light source comprising:
a control system, wherein the control system is configured to:
receive laser clock data of a laser source; and
control, in a closed loop synchronized configuration, an actuation of a rotational actuator and a linear actuator based on at least the laser clock data to selectively position a plurality of loops of a set of spots on a material-coated portion of a rotatable drum,
wherein for each loop, the set of spots are positioned such that the set of spots comprise:
a first set of spots arranged in a first spiral pattern from a first end of the rotational drum to a second end of the rotational drum;
a set of second end transition spots arranged in a turn-around portion near the second end of the rotational drum;
a second set of spots arranged in a second spiral pattern from the second end of the rotational drum to the first end of the rotational drum, wherein the first set of spots and the second set of spots are interleaved such that spots from the second set of spots do not overlap with spots from the first set of spots; and
a set of first end transition spots arranged in a turn-around portion near the first end of the rotational drum.

25. A method comprising:
receiving laser clock data of a laser source configured to direct pulsed illumination to a set of spots on a material-coated portion of a rotatable drum for exciting a plasma-forming target material and emitting broadband light as a rotational actuator rotates the rotatable drum and a linear actuator translates the rotatable drum in an axial direction;
controlling, in a closed loop synchronized configuration, an actuation of the rotational actuator and the linear actuator based on at least the laser clock data to selectively position a plurality of loops of the set of spots on the material-coated portion of the rotatable drum,
wherein for each loop, the set of spots are positioned such that the set of spots comprise:
a first set of spots arranged in a first spiral pattern from a first end of the rotational drum to a second end of the rotational drum;
a set of second end transition spots arranged in a turn-around portion near the second end of the rotational drum;
a second set of spots arranged in a second spiral pattern from the second end of the rotational drum to the first end of the rotational drum, wherein the first set of spots and the second set of spots are interleaved such that spots from the second set of spots do not overlap with spots from the first set of spots; and
a set of first end transition spots arranged in a turn-around portion near the first end of the rotational drum; and
recoating previously targeted spots of the rotatable drum with the plasma-forming target material.
